(19) United States
(12) Patent Application Publication
(10) Pub. No.: US 2010/0281441 A1
(43) Pub. Date: Nov. 4, 2010

(54) Portable Electronic Apparatus

(75) Inventors: James Eldon, Fleet Hants (GB); Ricky Barnett, St Albans (GB)

Correspondence Address: Nokia, Inc., 6021 Connection Drive, MS 2-5-520, Irving, TX, 75039, US

(73) Assignee: NOKIA CORPORATION, Espoo (FI)

(21) Appl. No.: 12/520,440

(22) PCT Filed: Dec. 21, 2006
(86) PCT No.: PCT/EP06/12639

§ 371 Date: May 11, 2010

(51) Int. Cl. G06F 3/01; H05K 5/00

(52) U.S. Cl. 715/864; 361/724; 715/866

(57) ABSTRACT

A portable electronic apparatus comprising a first part with a first user interface, the first user interface extending along a first plane, and a second part with a second user interface, the second user interface extending along a second plane, the first and second parts arranged to be movable with respect to one another along an axis to provide second user interface retracted and in-use configurations, wherein the apparatus is arranged such that relative movement of the first and second parts along the axis provides the second user interface in the retracted configuration in which the second user interface is stowed away from use, the second user interface plane being in a different plane away from the first plane, and relative movement of the first and second parts along the axis provides the second user interface in the in-use configuration in which the second user interface has been moved from the stowed away position into an in-use position in which the second user interface plane has been moved relatively towards the first plane.

The invention relates to a portable electronic apparatus, not necessarily an apparatus which provides mobile telephony function and which may be handheld in use.

### BACKGROUND

A known mobile telephone includes two parts which are slidable relative to one another between an open configuration and a closed configuration. A lower part includes a keypad which is accessible only in the open configuration, and an upper part includes a display. When the telephone is in the open configuration, the step down at the transition between the upper and lower parts may be considered to make the telephone cumbersome for a user, or be considered to be aesthetically displeasing.

The listing or discussion of a prior-published document in this specification should not necessarily be taken as an acknowledgement that the document is part of the state of the art or is common general knowledge.

### SUMMARY

According to a first aspect of the invention, there is provided a portable electronic apparatus comprising

a first part with a first user interface, the first user interface extending along a first plane, and

a second part with a second user interface, the second user interface extending along a second plane,

the first and second parts arranged to be movable with respect to one another along an axis to provide second user interface retracted and in-use configurations,

wherein the apparatus is arranged such that relative movement of the first and second parts along the axis provides the second user interface in the retracted configuration in which the second user interface is stowed away from use, the second user interface plane being in a different plane away from the first plane, and relative movement of the first and second parts along the axis provides the second user interface in the in-use configuration in which the second user interface has been moved from the stowed away position into an in-use position in which the second user interface plane has been moved relatively towards the first plane.

The first and second planes may substantially form the same continuous plane in the in-use configuration.

The second user interface may be arranged to be stacked behind the first user interface in the retracted configuration.

The second user interface plane may be moved towards the first plane in the in-use configuration.

The first and second parts may be arranged to be slidably movable with respect to one another along the axis to provide the second user interface configuration.

The first and second parts may be arranged to be slidably movable with respect to one another along a longitudinal axis of the apparatus to provide the second user interface configuration.

The second user interface plane may be moved relative to the second part in providing the in-use and retracted configurations.

The second user interface plane may be moved relative to the axis in providing the in-use and retracted configurations.

The second user interface plane may be moved substantially perpendicular to the axis in providing the in-use and retracted configurations.

The second user interface plane may be moved substantially towards and away from the axis in providing the in-use and retracted configurations.

The second user interface may be provided in the retracted and in-use configurations by relative movement of the first and second parts away from one another along the axis.

The second user interface may be provided in the retracted configuration by relative movement of the first and second parts away from one another along the axis.

The second user interface may be provided in the in-use configuration by relative movement of the first and second parts away from one another along the axis.

The second user interface may be provided in the retracted and in-use configurations by a biasing mechanism.

The second user interface may be provided in the retracted configuration by a biasing mechanism.

The second user interface may be provided in the in-use configuration by a biasing mechanism.

The apparatus may be arranged to hold the second user interface in the in-use configuration by acting against a biasing mechanism arranged to provide the second user interface in the retracted configuration.

The first user interface may comprise a user output interface.

The first user interface may comprise a user input interface.

The first user interface may comprise a user output interface and a user input interface.

The second user interface may comprise a user input interface.

The second user interface may comprise a user output interface.

The second user interface may comprise a user input and output interface.

The first and second parts may be external housing parts of the apparatus.

According to a second aspect of the invention, there is provided a method of providing a portable electronic apparatus user interface for use, comprising
moving a first part with a first user interface, the first user interface extending along a first plane, and a second part with a second user interface, the second user interface extending along a second plane, with respect to one another along an axis to provide second user interface retracted and in-use configurations,
wherein the apparatus is arranged such that relative movement of the first and second parts along the axis provides the second user interface in the retracted configuration in which the second user interface is stowed away from use, the second user interface plane being in a different plane away from the first plane, and relative movement of the first and second parts along the axis provides the second user interface in the in-use configuration in which the second user interface has been moved from the stowed away position into an in-use position in which the second user interface plane has been moved relatively towards the first plane.

According to a third aspect of the invention, there is provided a portable electronic apparatus comprising
a first means for housing with a first means for user interfacing, the first means for user interfacing extending along a first plane, and
a second means for housing with a second means for user interfacing, the second means for user interfacing extending along a second plane,
the first and second means for housing arranged to be movable with respect to one another along an axis to provide second means for user interfacing retracted and in-use configurations,
wherein the apparatus is arranged such that relative movement of the first and second means for housing along the axis provides the second means for user interfacing in the retracted configuration in which the second means for user interfacing is stowed away from use, the second means for user interfacing plane being in a different plane away from the first plane, and relative movement of the first and second means for housing along the axis provides the second means for user interfacing in the in-use configuration in which the second means for user interfacing has been moved from the stowed away position into an in-use position in which the second means for user interfacing plane has been moved relatively towards the first plane.

According to a fourth aspect of the invention, there is provided a computer program for controlling the state of the second user interface of the apparatus of the first aspect according to the detected configuration of the apparatus.

According to a fifth aspect of the invention, there is provided a portable electronic apparatus comprising
a first part extending along a first plane, and
a second part with a user interface, the second part user interface extending along a second plane,
the first and second parts arranged to be movable with respect to one another along an axis to provide second part user interface retracted and in-use configurations,
wherein the apparatus is arranged such that relative movement of the first and second parts along the axis provides the second part user interface in the retracted configuration in which the second part user interface is stowed away from use, the second part user interface plane being in a different plane away from the first plane, and relative movement of the first and second parts along the axis provides the second part user interface in the in-use configuration in which the second part user interface has been moved from the stowed away position into an in-use position in which the second part user interface plane has been moved relatively towards the first plane.

The present invention includes one or more aspects, embodiments or features in isolation or in various combinations whether or not specifically stated (including claimed) in that combination or in isolation.

### BRIEF DESCRIPTION OF THE DRAWINGS

A description is now given, by way of example only, with reference to the accompanying drawings, in which:—

FIG. 1 shows a known slide phone;

FIG. 2 shows a first portable electronic apparatus in a retracted configuration;

FIG. 3 shows the apparatus of FIG. 2 in an in-use configuration;

FIG. 4 shows a second portable electronic apparatus in a retracted configuration;

FIG. 5 shows the apparatus of FIG. 4 moving towards an in-use configuration;

FIG. 6 shows the apparatus of FIG. 4 moving towards an in-use configuration;

FIG. 7 shows the apparatus of FIG. 4 moving towards an in-use configuration;

FIG. 8 shows the apparatus of FIG. 4 in an in-use configuration;

FIG. 9 shows a detent mechanism of the apparatus of FIG. 4;

FIG. 10 shows the apparatus of FIG. 4 moving towards a retracted configuration;

FIG. 11 shows the apparatus of FIG. 4 moving towards a retracted configuration;

FIG. 12 shows the apparatus of FIG. 4 moving towards a retracted configuration;

FIG. 13 shows the apparatus of FIG. 4 in a retracted configuration;

FIG. 14 is a schematic diagram of circuitry of the apparatus of FIG. 4.

FIGS. 15-23 show implementation details of an apparatus and a biasing mechanism according to one embodiment of the present invention in which:

FIG. 15 shows a partially open apparatus in plan view, with certain features which would ordinarily be hidden to a user highlighted for explanation;

FIG. 16 shows an underside view of a component of a second part and a internal side view of a portion of the first part;

FIG. 17 shows an isometric view of the interior of the second part of FIG. 16;

FIG. 18 shows an isometric view of the second part with the keymat in a retracted configuration;

FIG. 19 shows an isometric view of the second part with the keymat in a in-use configuration;

FIG. 20 shows the apparatus in an open in-use configuration;

FIG. 21 shows the apparatus in a closed configuration;

FIG. 22 shows a side view highlighting some internal features of the first and second parts in an open in-use configuration of the apparatus;

FIG. 23 shows details of a cam arrangement of a biasing mechanism.

### DETAILED DESCRIPTION

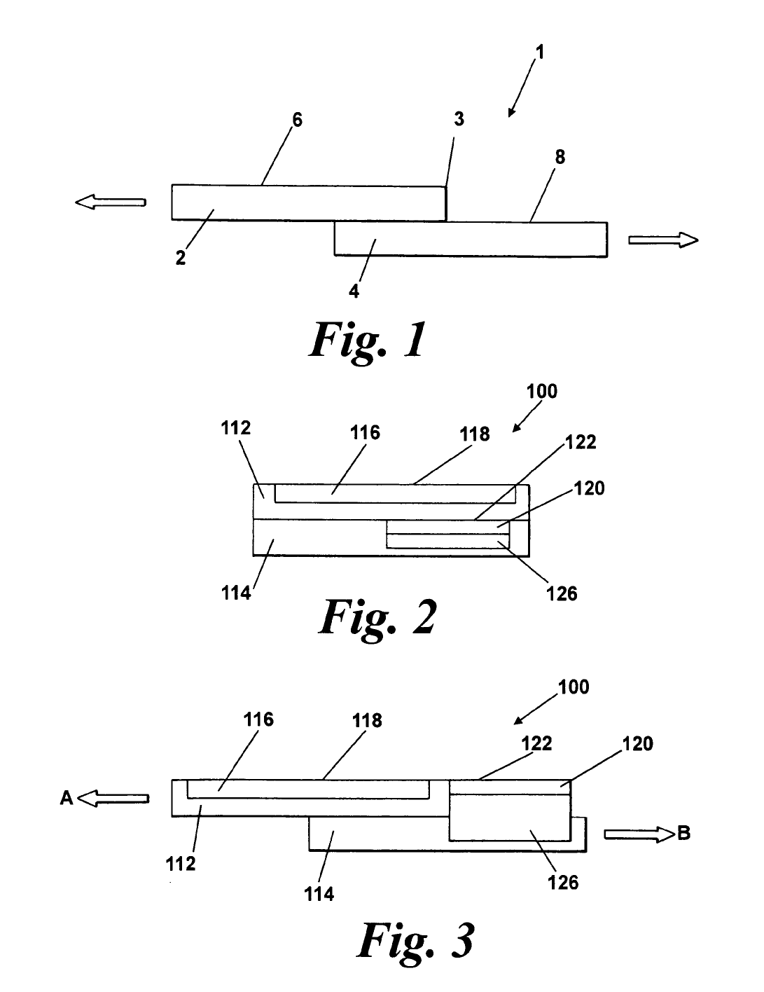

FIG. 1 shows a known slide phone 1 including an upper part 2 and a lower part 4. The upper part 2 has a display 6 and the lower part 4 has a keypad 8. The upper and lower parts 2, 4 are moved in the direction of the arrows to move the phone 1 from the closed configuration to the open configuration, thereby to reveal the keypad 8. At the transition between the upper and lower parts 2, 4, a step down 3 hinders use of the keypad 8.

FIGS. 2 and 3 show a first portable electronic apparatus 100 having a first part 112 and a second part 114. In this case, the apparatus is a portable mobile telephone.

The first part 112 includes a first user interface 116 extending along a first plane 118. The second part 114 includes a second user interface 120 extending along a second plane 122. For reasons of clarity, the figures do not show the details of the user interfaces.

The first and second parts 112, 114 are arranged to be movable with respect to one another to provide retracted and in-use configurations of the second user interface 120.

FIG. 2 shows the apparatus 100 in a retracted configuration in which the second user interface 120 is stowed away from use beneath the first user interface 116, and in which the second plane 122 is in a different plane away from the first plane 118.

As shown in FIG. 3, movement of the first and second parts 112, 114 away from each other moves the apparatus into an in-use configuration. The first part 112 is moved in the direction of arrow A and the second part 114 in the direction of arrow B.

In an in-use configuration, the second user interface 120 has been moved from the stowed away position into an in-use position in which the second plane 122 has been moved relatively towards the first plane 118. In this embodiment, the first and second planes 118, 122 are in substantially the same plane when in an in-use configuration. In another embodiment, the second plane 122 is moved relatively towards the first plane 118 in an in-use configuration but lies in a different plane to the first plane 118 (but the planes 118, 122 are closer together in the in-use configuration than in the retracted configuration).

The apparatus includes a biasing mechanism 126 whereby the second user interface 120 is biased towards its in-use position in an in-use configuration. The biasing mechanism is shown in its compressed form in FIG. 2 and in its expanded form in FIG. 3, such that the bias acts to move the apparatus into the in-use configuration. In one example, the biasing mechanism 126 comprises a compression spring arranged to bias the second user interface 120 into the in-use configuration.

In this embodiment, to return the apparatus to the retracted configuration, the second user interface 120 is pushed downwardly until the second part 114 can be slid underneath the first part 112, to return to the configuration shown in FIG. 2.

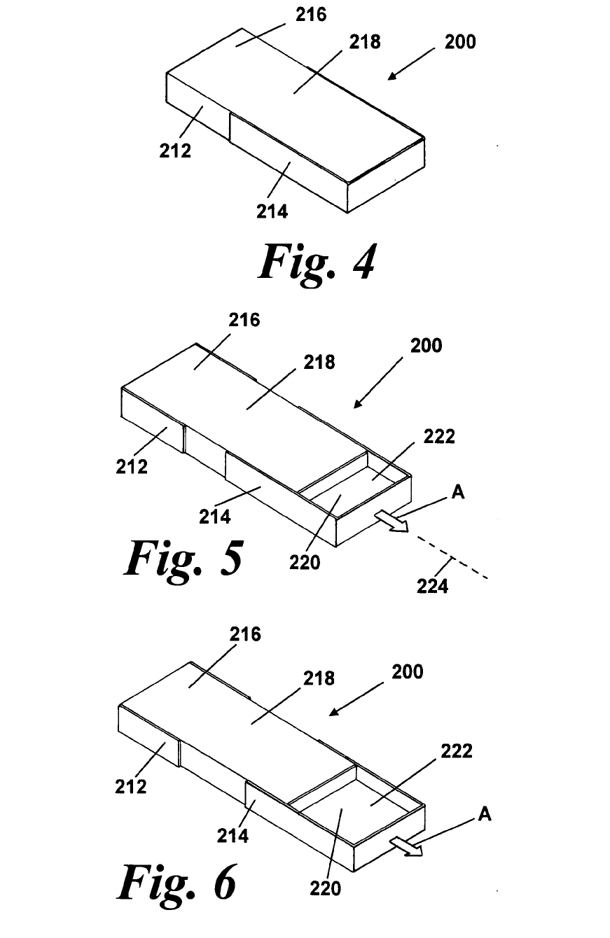

FIGS. 4 to 13 show a second portable electronic apparatus 200 having a first part 212 and a second part 214.

The first part 212 includes a first user interface 216 extending along a first plane 218. The second part 214 includes a second user interface 220 extending along a second plane 222 (shown in FIGS. 5 to 8 and 10 to 12). For reasons of clarity, the figures do not show the details of the user interfaces.

The first and second parts 212, 214 are arranged to be movable with respect to one another along an axis 224 (shown in FIG. 5) to provide retracted and in-use configurations of the second user interface 220.

Relative movement of the first and second parts 212, 214 along the axis 224 provides the second user interface 220 in a retracted configuration in which the second user interface 220 is stowed away from use, and in which the second plane 222 is in a different plane away from the first plane 218. A retracted configuration is shown in FIG. 4.

In addition, relative movement of the first and second parts 212, 214 along the axis 224 provides the second user interface 220 in an in-use configuration in which the second user interface 220 has been moved from the stowed away position into an in-use position in which the second plane 222 has been moved relatively towards the first plane 218. In one embodiment, the first and second planes 218, 222 are in substantially the same plane when in an in-use configuration. In another embodiment, the second plane 222 is moved relatively towards the first plane 218 in an in-use configuration but lies in a different plane to the first plane 218. An in-use configuration is shown in FIG. 8.

The apparatus includes a biasing mechanism (not shown) whereby the second part 214 is biased towards its position in a retracted configuration, and whereby the second user interface 220 is also biased towards its position in an in-use configuration.

The apparatus 200 includes a detent mechanism 228, as shown in FIG. 9. The detent mechanism 228 includes a lip 230 on the second user interface 220 which engages a corresponding shoulder 232 on the first user interface 216. When the lip 230 engages the shoulder 232, the detent mechanism 228 acts to prevent movement of the second part upwardly or downwardly or towards the first part 212. The lip 230 and/or shoulder 232 could be comprised on other regions of the parts 212, 214.

FIGS. 4 to 8 show the second part 214 being moved from a retracted configuration to an in-use configuration.

In FIG. 4, the second part 214 is in a retracted configuration with the second user interface 220 stowed beneath the first user interface 216.

Movement of the second part 214 along the axis 224 in the direction of arrow A causes the second part 214 to separate from the first part 212, partially exposing the second user interface 220, as shown in FIG. 5.

FIG. 6 shows further movement of the second part 214 away from the first part 212, in the direction of arrow A. In FIG. 6, the second part 214 is in the position it occupies when in an in-use configuration. The second user interface 220 is prevented from moving upwardly under the influence of the biasing mechanism by engagement of the lip 230 with the underside of the first user interface 216.

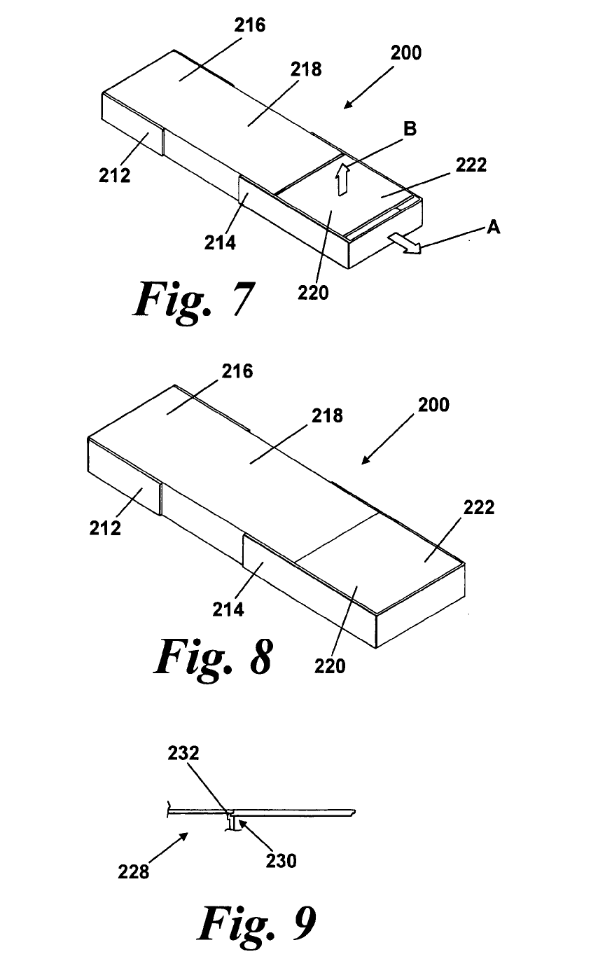

FIG. 7 shows a slight further movement (in the direction of arrow A) of the second part 214 away from the first part 212, which frees the second user interface 220 and allows it to be urged upwardly (in the direction of arrow B) by the biasing mechanism such that its plane 222 lies in substantially the same plane as the first plane 218.

When the second part 214 is released, the biasing mechanism causes the second part 214 to move towards the first part 212, as shown in FIG. 8, until the lip 230 on the second user interface 220 engages the shoulder 232 on the first user interface 216, thereby locking the two interfaces 216, 220 together. In this configuration, the second user interface 220 acts to prevent the second part 214 from returning to its position in a retracted configuration under the influence of the biasing mechanism.

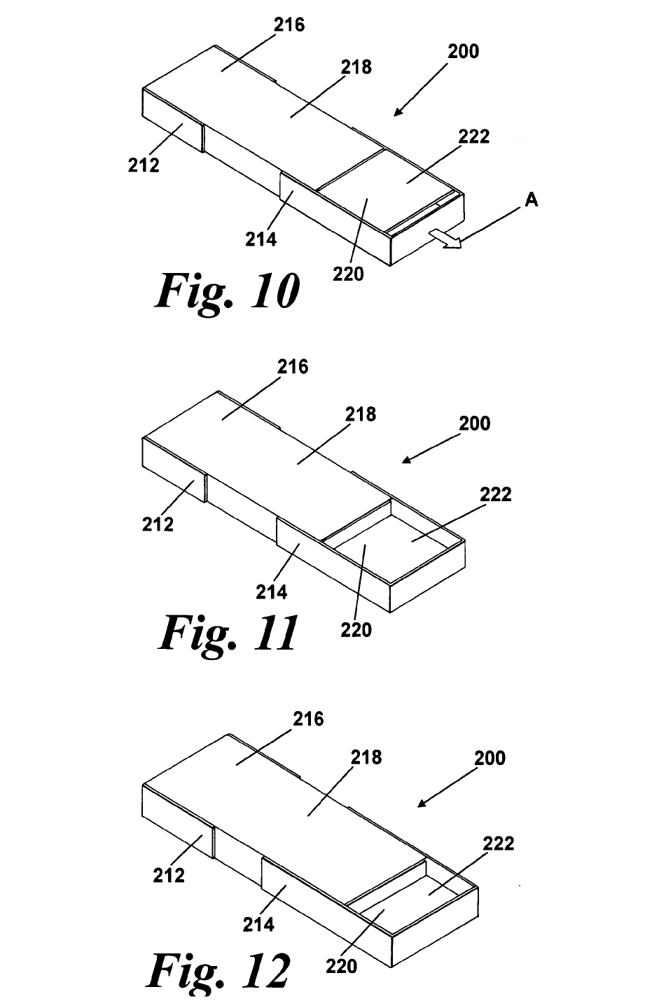

FIGS. 10 to 13 show the second part 214 being moved from an in-use configuration to a retracted configuration.

FIG. 10 shows a slight movement (in the direction of arrow A) of the second part 214 away from the first part 212, which frees the second user interface 220 from the detent mechanism 228.

The second user interface 220 can then be pushed downwardly against the action of the biasing mechanism, as shown in FIG. 11. In an alternative embodiment, the biasing mechanism moves the second user interface downwardly when the second user interface 220 is freed under the movement shown in FIG. 10.

When the second user interface 220 reaches a position in which the lip 230 is below the first user interface 216, the biasing mechanism is free to move the second part 214 towards a retracted configuration, as shown in FIG. 12.

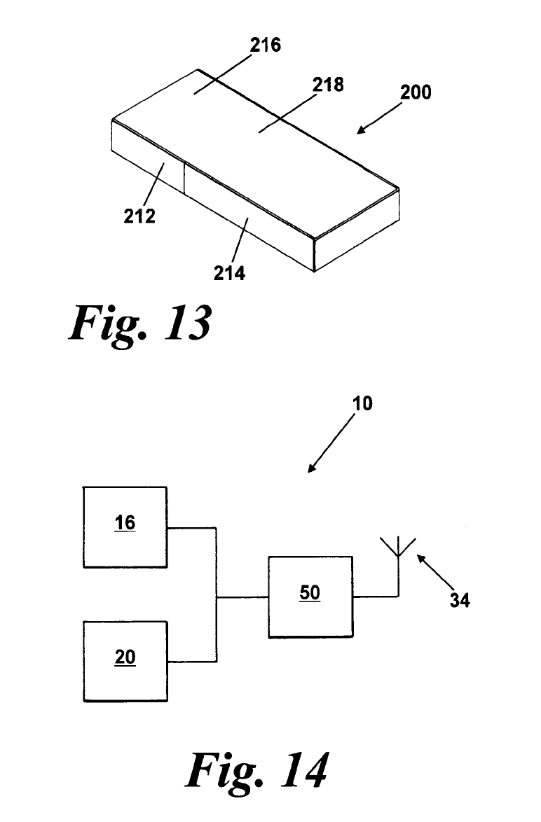

FIG. 13 shows the second part 214 having returned to a retracted configuration.

In a variant, the second user interface 220 is caused to move towards the plane 218 of the first user interface 216 by one or more cam surfaces during movement of the second part 214 towards an in-use configuration. The various biasing mechanisms discussed may comprise one or more spring elements and/or one or more cam arrangements.

FIG. 14 is a schematic diagram of circuitry of the apparatus 200. The apparatus includes circuitry 50 in communication with the first and second user interfaces 216, 220, and an antenna 234 in communication with the circuitry 50. The circuitry 50 includes all processing circuitry, memory and transceiver circuitry of the apparatus 200. In a variant, the circuitry 50 omits the transceiver circuitry and the apparatus 200 does not include an antenna.

The circuitry 50 may be configured to deactivate (e.g. power down/off and/or lock from use) the second user interface 120, 220 when the apparatus is in the retracted configuration and re-activate (e.g. power up and/or allow to be used) the second user interface 120, 220 when the second user interface 120, 220 is in an in-use position. In such embodiments, sensors would be required to detect the configuration of the apparatus/position of the user interface, which will provide input for a computer program (stored on a carrier) for controlling the state of the second user interface 120, 220.

The first/second user interface may comprise a display and/or keypad/touchpad.

The movement of the second user interface towards the plane of the first user interface may be during the movement of the parts away from one another or after the parts have been moved to a particular relative position.

The first/second user interfaces may be linked. For example, user input on the second user interface may be displayed on a display on the first user interface (or vice versa). Furthermore, user inputs of the first and second user interfaces may be combined in the in-use configuration to provide a single user input interface, e.g. two parts of a QWERTY keyboard being combined, or two parts of a single display or touchscreen being combined.

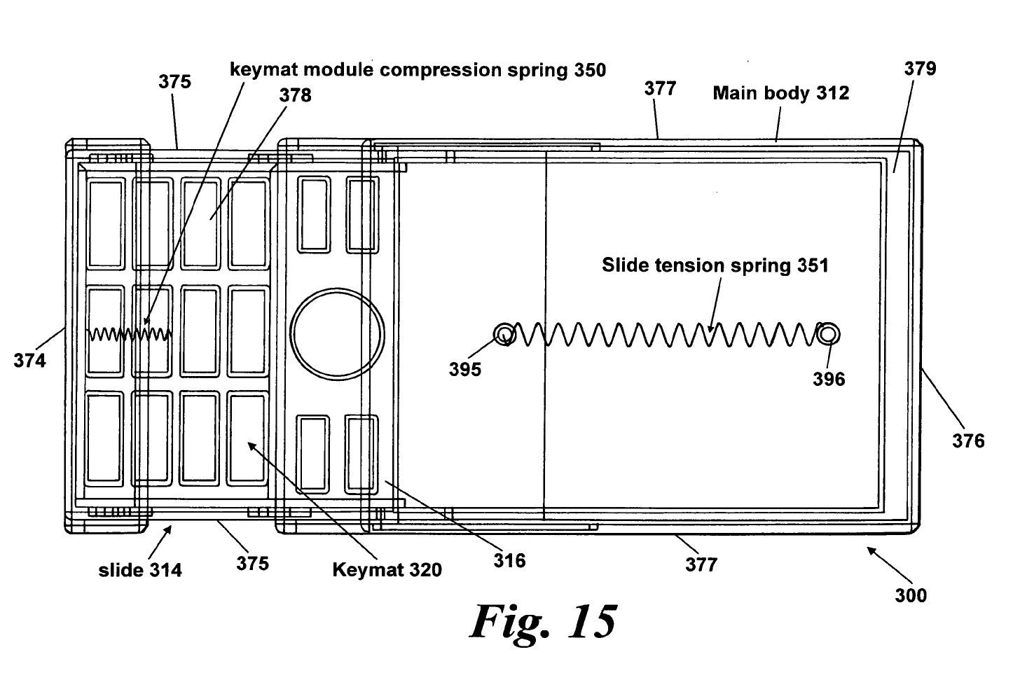

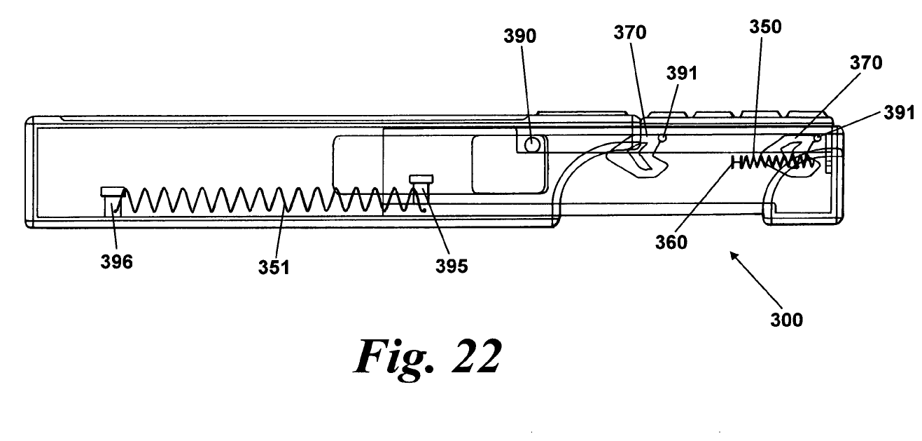

One specific embodiment of a biasing mechanism and apparatus 300 are detailed in FIGS. 15-23. The apparatus 300 comprises a first part 312 (main body) and a second part 314 (slide). The main body 312 has a top side face 376 joined to two lateral side faces 377, all of which extend perpendicularly from a user facing surface 379 of the apparatus 300. The face opposite the top face 376 is open.

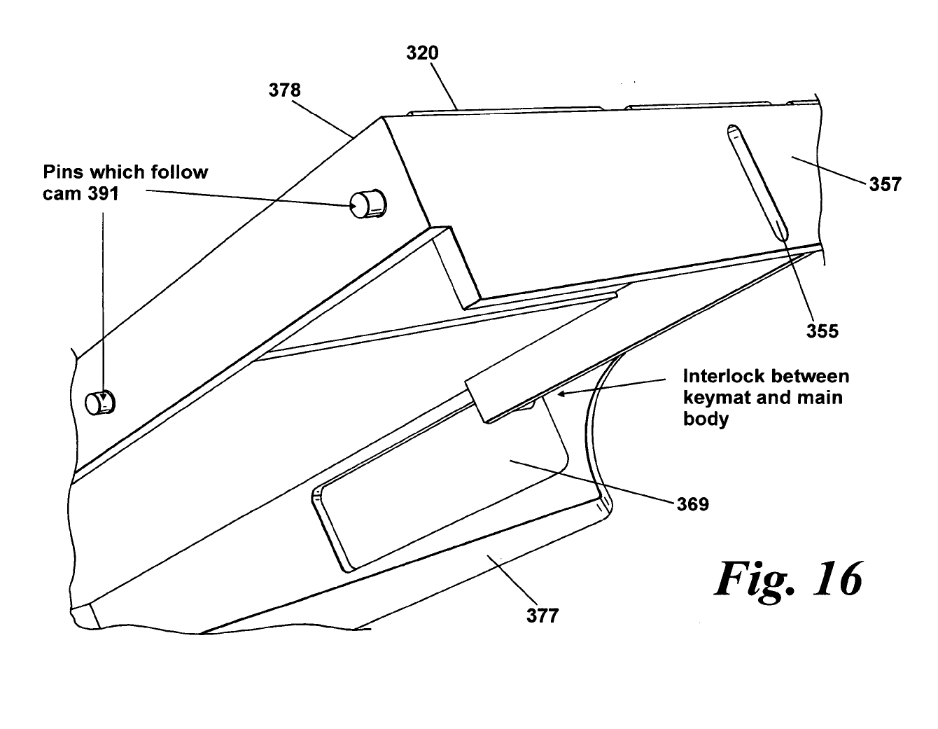

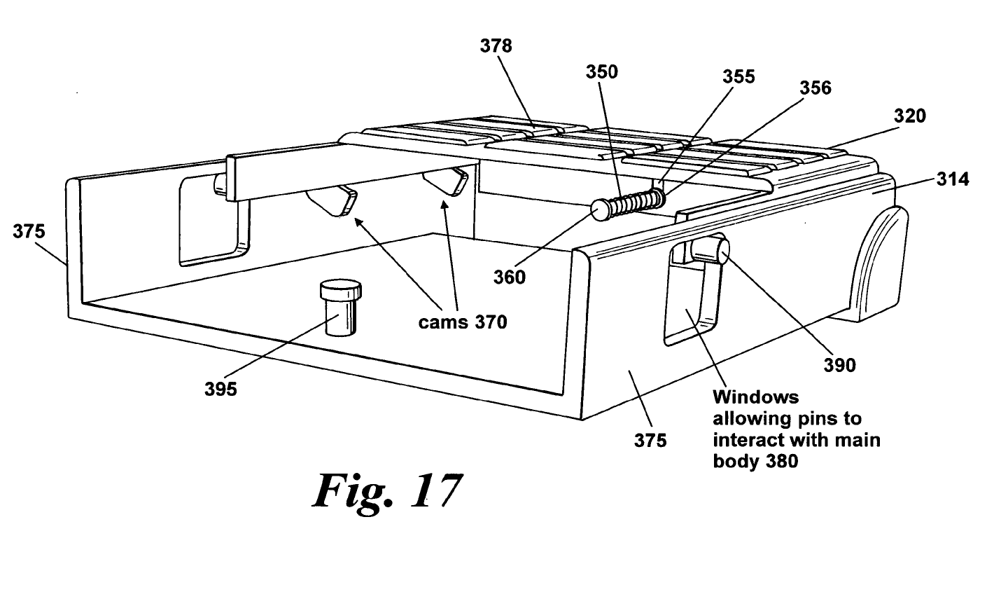

The slide 314 has a base 374 joined to two lateral sides 375, all of which are perpendicular to a user facing surface 378 of the apparatus. The user facing surface 378 comprises a keymat 320 which can move relative to the base and lateral sides 374, 375 of the slide 314. The keymat 320 is attached to the base 374 via a slot 355 in a face 357 of the keymat 320 which is perpendicular to the user facing surface 378. The base 374 comprises a pin 360 which extends internally from the base along the longitudinal axis of the slide 314. The slot 355 and pin 360 are arranged so that the pin 360 can fit through the slot 355 to hold the keymat 320 with the slide base/sides 374/375 (FIG. 16, 17). The keymat 320 is biased against the slide base/sides 374/375 by means of a compression spring 350 and washer 356 located around the pin 360 and located internal to the slide 314 (FIG. 17). This bias (together with the associated friction between the face 357 of the keymat 320 and the internal face of the base 374) keep the keymat 320 from moving relative to the base/sides 374/375 unless the compression bias is released (release by engagement of side of recess 369 and pin 390, discussed later (FIG. 16)).

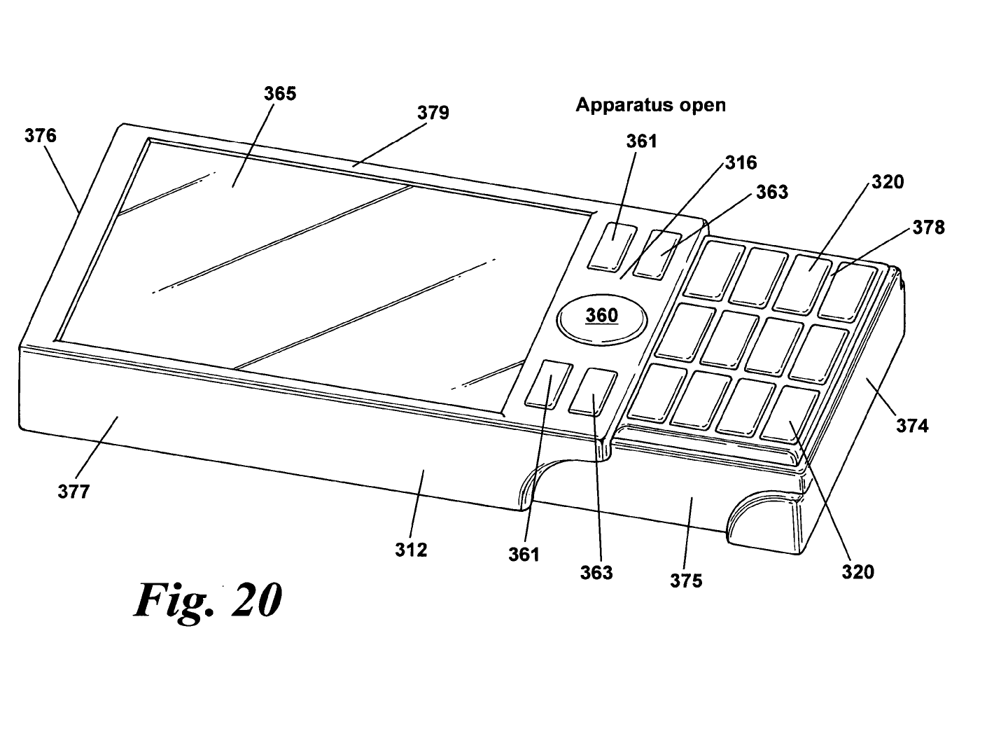

When assembled, the slide 314 is slideably fitted into the main body 312 so that it can slide in and out towards the top 376 of the main body 312 via the open face of the main body 312 (FIG. 20, 21). The keymat 320 can also move in an out with respect to the user facing surface 378 of the main body 312.

The main body 312 has a first user interface 316, 365 on the user facing surface 379 of the main body 312. The first user interface 316 comprises soft keys 361 adjacent a display 365, and also call handling keys 363 to allow a user to answer and cancel calls. A toggle key 360 is also provided on the first user interface 316. As previously mentioned, the keymat is the second user interface 320 of the slide 314.

The lateral sides 377 of the main body 312 comprise a recess 369 on an internal face, which are located adjacent the slide 314 (FIG. 16) when assembled. The ends of this recess 369 are used to engage with a pin 390 on the slide 314 to release engagement of the keymat 320 with the base 374.

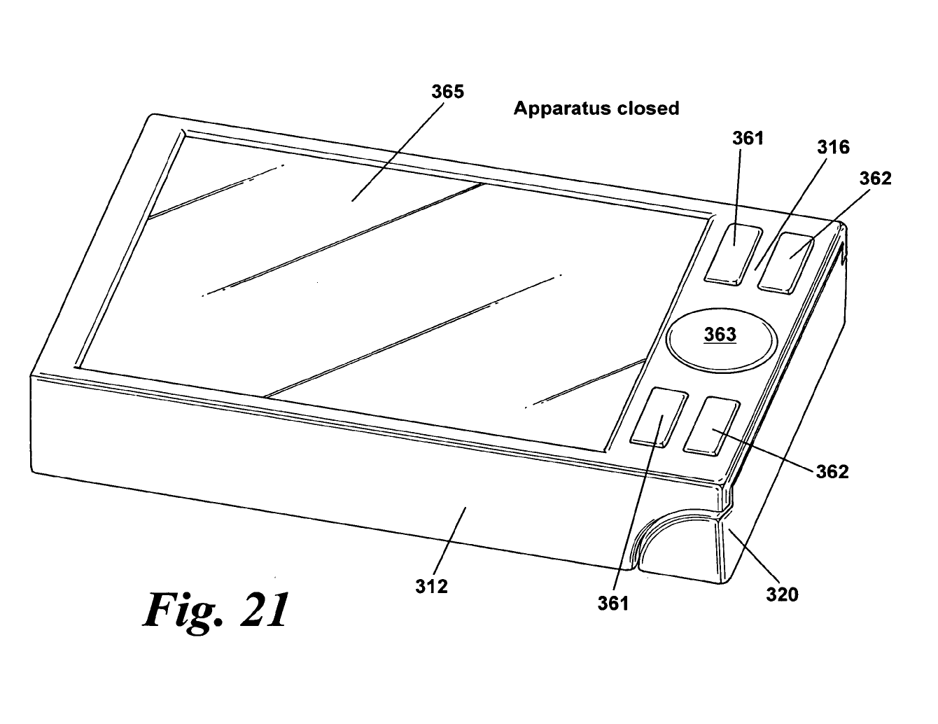

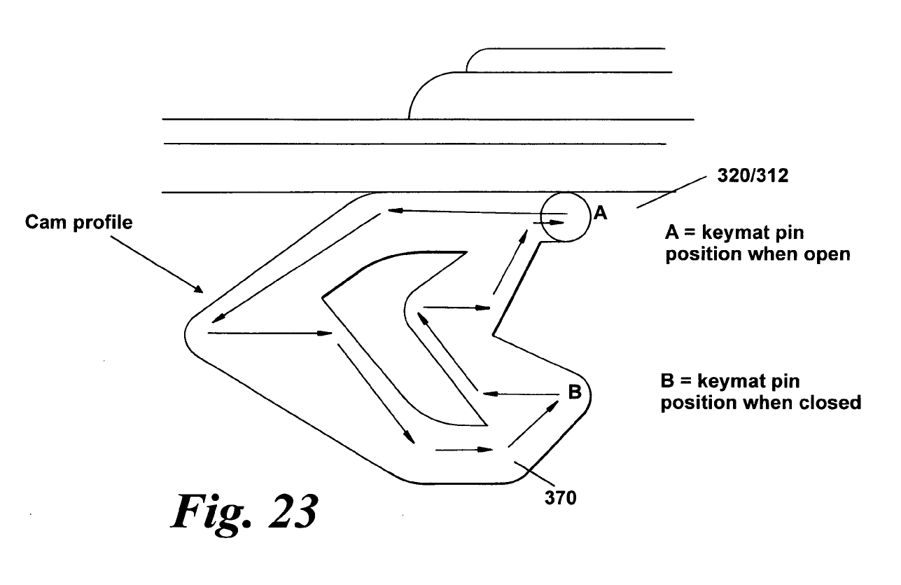

A tension spring 351 is provided internally to the main body/slide 312,314 between end stops 396, 395. The end stop 396 is fixed to the main body 312 and the end stop 395 is fixed to the slide 314. The tension spring 351 acts to bias the main body and slide 312, 314 into a closed configuration (FIG. 21) in which the keymat 320 is stowed away from use. Action against the bias provided by the spring 351 will open the apparatus 300 into an open configuration in which the keymat 320 is in an in-use configuration (FIG. 20). The movement of the keymat 320 into the in-use and retracted configurations is provided by means of a cam biasing mechanism (FIG. 23).

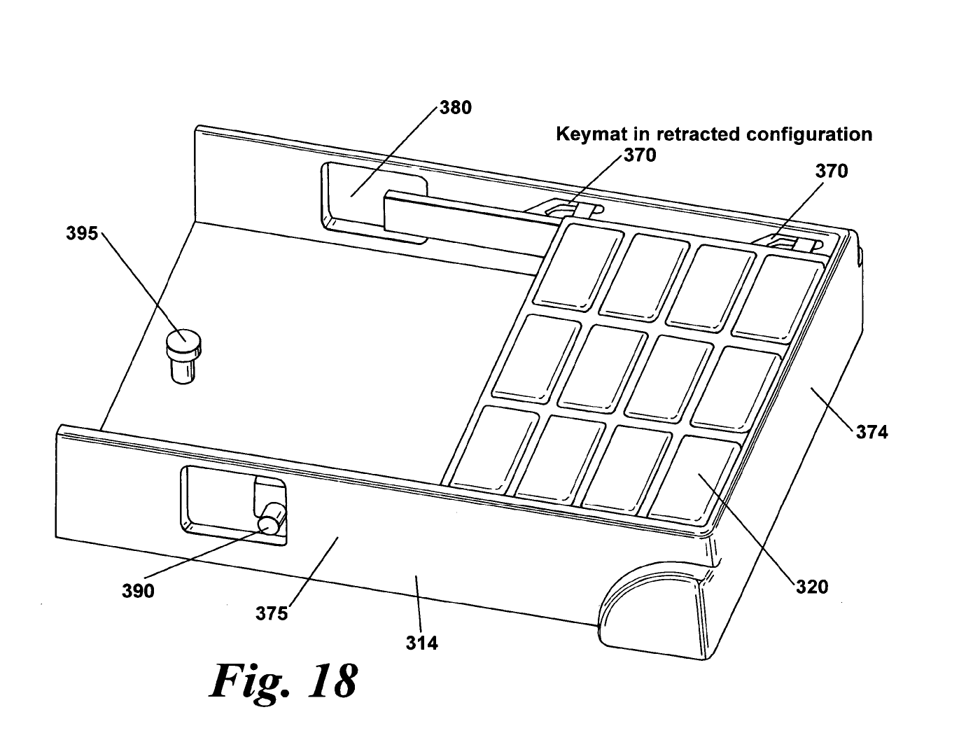

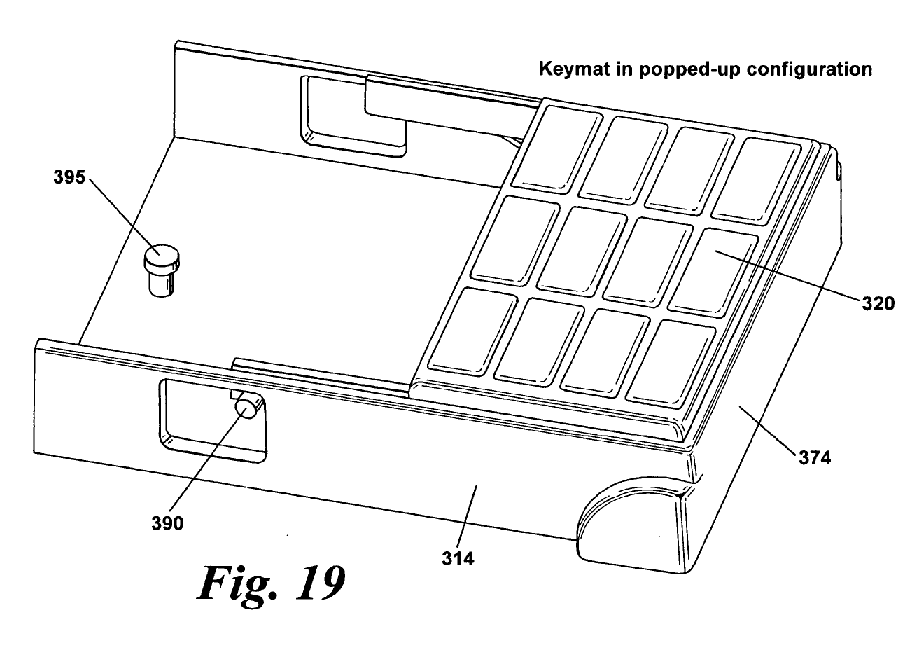

The cam biasing mechanism is provided by engagement of the pins 390 of the keymat 320 with cams 370 located on the internal faces of the lateral sides 375 of the slide 314. The cam profile is such that pins 390 are held is two possible detent positions (A, B of FIG. 23), one in which the keymat 320 is provided for use (FIG. 19, 20, 21 and position A of FIG. 23), and one in which the keymat is retracted from use (FIG. 18, FIG. 21, position B of FIG. 23).

The pins 390 are moved between the two cam positions by acting against the bias (tension) provided by the tension spring 351. From the closed configuration of the apparatus 300 (FIG. 21), pulling the slide 314 away from the main body 312 along the longitudinal axis moves the pins 391 (anticlockwise in FIG. 23) from position B to position A. This pulling action puts the compression spring 350 into further compression (by virtue of pin 390 engaging with a corresponding end of recess 369 of the main body 312, FIG. 16), releasing the engagement of the keymat 320 with the base 374 and allowing the keymat 320 to be guided by the cam to the in-use configuration.

From the open configuration, further pulling against the bias provided by the tension spring 351 releases the engagement of pin 391 from detent position A, and the cam guides the pins 391 (anticlockwise in FIG. 23) to position B. Similarly, the pulling action puts the compression spring 350 into further compression, releasing the engagement of the keymat 320 with the base 374 and allowing the keymat 320 to be guided by the cam to the in-use configuration.

In the embodiments shown in the figures, a number of pins 391 and cams 370 are provided. Fewer or more cam/pins may be provided in other embodiments.

It will be appreciated that the aforementioned circuitry may have other functions in addition to the mentioned functions, and that these functions may be performed by the same circuit.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features. In view of the foregoing description it will be evident to a person skilled in the art that various modifications may be made within the scope of the invention.

While there have been shown and described and pointed out fundamental novel features of the invention as applied to preferred embodiments thereof, it will be understood that various omissions and substitutions and changes in the form and details of the devices and methods described may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto. Furthermore, in the claims means-plus-function clauses are intended to cover the structures described herein as performing the recited function and not only structural equivalents, but also equivalent structures. Thus although a nail and a screw may not be structural equivalents in that a nail employs a cylindrical surface to secure wooden parts together, whereas a screw employs a helical surface, in the environment of fastening wooden parts, a nail and a screw may be equivalent structures.

1-28. (canceled)

29. An apparatus comprising:
a first part extending along a first plane; and
a second part slidably connected with the first part, the second part having a second part user interface, the second part user interface having a second plane,
the first part and the second part configured to be movable with respect to each other along an axis to provide the second part user interface in a retracted configuration and the second part user interface in an in-use configuration,
the apparatus being configured such that relative movement of the second part toward the first part along the axis provides the second part user interface biased in the retracted configuration and relative movement of the second part away from the first part along the axis provides the second part user interface in the in-use configuration, the second plane moving relatively towards the first plane when the second part user interface is in the in-use configuration.

30. An apparatus according to claim 29, wherein the first part comprises a first part user interface.

31. An apparatus according to claim 29, wherein the second part user interface is capable of biasing in the in-use configuration.

32. An apparatus according to claim 29, wherein the apparatus is configured to hold the second part user interface in the in-use configuration by acting against a biasing mechanism, wherein the biasing mechanism is configured to provide the second part user interface in the retracted configuration.

33. An apparatus according to claim 32, wherein the biasing mechanism is provided by a spring connected to a main body, the main body comprising the first part user interface and a slide coupled with the second part user interface.

34. An apparatus according to claim 32, further comprising a cam biasing mechanism and pins, capable of holding the second user interface in the in-use configuration or in the retracted configuration.

35. An apparatus according to claim 29, wherein the first plane and second plane are substantially the same when the apparatus is in the in-use configuration.

36. An apparatus according to claim 29, wherein the second part user interface is configured to be stacked behind the first part user interface in the retracted configuration.

37. An apparatus according to claim 29, wherein the second part user interface is configured to move relative to the second part to provide the in-use and retracted configurations.

38. An apparatus according to claim 29, wherein the second part user interface is configured to move relative to the axis in providing the in-use configuration and the retracted configuration.

39. An apparatus according to claim 29, wherein the second part user interface is configured to move substantially perpendicular to the axis in providing the in-use configuration and the retracted configuration.

40. An apparatus according to claim 29, wherein the second part user interface is configured to move substantially towards and away from the axis in providing the in-use configuration and the retracted configuration.

41. An apparatus according to claim 29, wherein the second part user interface is provided in the retracted configuration and in the in-use configuration by relative movement of the first part and the second part away from each other along the axis.

42. A method comprising:
providing a first part extending along a first plane;
providing a second part slideably connected with the first part, the second part having a second part user interface, the second part user interface having a second plane;
configuring the first part and the second part to be movable with respect to each other along an axis to provide the second part user interface in a retracted configuration and the second part user interface in an in-use configuration; and
configuring the apparatus such that relative movement of the second part toward the first part along the axis provides the second part user interface biased in the retracted configuration and relative movement of the second part away from the first part along the axis provides the second part user interface in the in-use configuration, the second plane moving relatively towards the first plane when the second part user interface is in the in-use configuration.

43. A computer program product comprising a computer-readable medium bearing computer program code embodied therein for use with a computer, the computer program code comprising:
code for detecting an in-use configuration of an apparatus when a second part is biased in an open configuration;
code for detecting a retracted configuration of an apparatus when the second part is biased in a closed configuration;
code for manipulating a user interface when the apparatus transitions from the in-use configuration to the retracted configuration; and
code for manipulating the user interface when the apparatus transitions from the retracted configuration to the in-use configuration,
wherein the second part is slideably connected with a first part, the second part having the user interface, the first part and the second part movable with respect to each other along an axis to provide the second part in the retracted configuration and the second part in the in-use configuration.
